(19) United States
(12) Patent Application Publication
(10) Pub. No.: US 2006/0061348 A1
(43) Pub. Date: Mar. 23, 2006

(54) High frequency oscilloscope probe with unitized probe tips

(76) Inventors: James E. Cannon, Colorado Springs, CO (US); Michael T. McTigue, Colorado Springs, CO (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/945,146

(22) Filed: Sep. 20, 2004

(51) Int. Cl. G01R 31/02

(52) U.S. Cl. 324/72.5

(57) ABSTRACT

Unitized probe tip assemblies of reduced size for a micro-browser use surface mount components in an isolation/coupling network that may include a parallel RC combination in series with a damping resistor. These surface mount components are soldered directly to one another without the use of a substrate. A pointed contact tip is soldered directly to one end of the surface mount components, and at the other end of those components is soldered the center conductor of a coaxial transmission line leading to a replication amplifier. A portion of the isolation/coupling network is enclosed within a supporting conductive shield that is also soldered to the outer conductive shield of the coaxial cable, which may be a semi-rigid micro coax (which might also be of a memory metal, such as Nitinol) that transitions into a flexible coaxial cable after leaving a slot in a sleeve that carries stationary and rotating rods (which might also be of a memory metal) to which the unitized probe tip assemblies are attached. In an alternate embodiment the isolation/coupling network may be a shaft of resistive diamond having a sharp tip at one end where it has a low bulk resistance the functions as a series damping resistance, which shaft also has toward the other end a much higher bulk resistance that functions as an isolation resistance that is also shunted by a coupling capacitance formed of a conductive pattern printed on the outside of the region of higher bulk resistance.

### REFERENCE TO RELATED APPLICATIONS

This application is related to other developments in the field of high frequency probes. As is well known and appreciated, the “mechanical” aspect of high frequency structures often have a significant effect on their electrical performance, so that sometimes it is somewhat artificial to describe certain important probe properties as “mechanical” and others as “electrical.” That said, it is not insensible to think of some outcomes as having been produced primarily through choices of physical parameters in three dimensions (“mechanical”), as opposed to circuit values for components in a schematic (“electrical”). For the sake of brevity concerning mechanical developments, U.S. patent application Ser. No. 10/829,725 entitled COMPLIANT MICRO-BROWSER FOR A HAND HELD PROBE filed 22 April by James E. Cannon, et al., and U.S. patent application Ser. No. 10/834,549 entitled UNBREAKABLE MICRO-BROWSER filed 28 Apr. 2004 by James E. Cannon are each hereby incorporated herein by reference. For the sake of brevity concerning electrical developments, U.S. Pat. No. 4,473,839 (Rush) entitled WIDE BANDWIDTH PROBE USING POLE-ZERO CANCELLATION and issued 10 May 1988, and U.S. Pat. No. 6,483,284 B1 (Eskeldson, et al.) also entitled WIDE-BANDWIDTH PROBE USING POLE-ZERO CANCELLATION and issued 19 Nov. 2002, are each hereby incorporated herein by reference.

### BACKGROUND OF THE INVENTION

The bandwidth of modern high performance DSOs (Digital Sampling Oscilloscopes) is sufficiently high (often in excess often gigahertz) that considerable attention has to be paid to how signals with such high frequency components are delivered to the 'scope. It is common for an input channel on the front panel to have a controlled characteristic impedance, such as 50 Ω. If the signal originates with a source that has that same characteristic impedance and that expects to be terminated, then a length of suitable coaxial cable can connected the 'scope to the source, and the input impedance of the 'scope will act as the desired termination. Beside the issue of the 'scope's frequency response, the main electrically troublesome issues with this arrangement are losses in the cable and the discontinuities presented by the RF connectors of the cable.

Unfortunately, more is generally demanded of a high performance wide-band DSO; it is often desired to probe locations within circuitry that neither expects nor tolerates a terminating load. That is, the classic case of connecting to a node of a circuit without loading it is required if the measurement is to be of any value. This sort of situation was first handled by passive high impedance attenuator probes, up to bandwidths of, say, 100 MHZ. The limitations of this approach soon become apparent as signal frequencies get even higher, and active probes became common.

There are two common general methods in use today to probe high frequency signals of several gigahertz and up using active probes. In one method the active amplifier is minimized as much as possible and located within the probe assembly itself, and as close as possible to the probe tip. The amplifier input presents a reasonable input impedance, while the output of the amplifier drives a cable connecting the probe assembly to the 'scope. It is not so much that this does not work; electrically it performs as needed. It results, however, in a rather bulky probe that often cannot be physically deployed where its services are needed because of the crowded nature of the circuit assembly being investigated. Frustrated users often graft short lengths ofwire onto the probe tip to reach the nodes of interest, with the outcome that the measured results are suspect owing to the presence of spurious reactances added by the short lengths of wire, and their unknown effects on the measurement.

Such troubles have led to the development of the second general method, which is the one that we shall principally be interested in. In this second method we appreciate at the outset that the amplifier (which we shall call a “replication amplifier”) is simply too big to allow it to remain right at the probe tip. This leads us to a compact “micro-browser” that carries ‘only’ the actual probe tip (a pointed contact) and a flexible shielded controlled impedance conductor. The flexible shielded controlled impedance conductor is a short length (say, about four inches) of transmission line, such as 50 Ω coaxial cable. It connects the probe tip to the replication amplifier. However, we can't simply connect (via the probe tip) the center conductor of that 50 Ω coaxial cable to a high speed high impedance node in a circuit; we must do so through an isolation coupling network, such as a parallel RC combination (e.g., 25 KΩ with 200 ff) that is as close to the probe tip as is possible. And to be on the safe side, we will even put a series damping resistance (say, 100 Ω) between the actual probe tip and the RC combination. The other side of the RC combination drives the center conductor of the coax at the probe end, while the replication amplifier end of the coaxial transmission line is terminated in the characteristic impedance of that coaxial cable.

It will immediately be appreciated that the above-described isolation/coupling network operates, in conjunction with the capacitance of the short length of coaxial cable, as an attenuator of high frequencies (a zero). Flat frequency response is restored by a compensatory frequency response in the replication amplifier (a pole). This technique has been termed “pole-zero cancellation” and is the (electrical) subject matter of the incorporated Patents to Rush and Eskeldson. Furthermore, the usual probe configuration is differential, so that there are two such probe tips, identical isolation/coupling networks, lengths of terminated coax and matched replication amplifiers. The outputs of the matched replication amplifiers are combined in a differential amplifier that drives the length of main coax (three or four feet) that leads to the 'scope.

As bandwidth has increased, there has also developed a need to make the probes small. The pole-zero cancellation technique has been adapted to this as well, by the development of the afore-mentioned micro-browsers. They have probe tip assemblies on one end with flexible coax cables emerging from the other and that couple to the replication amplifiers. These micro-browsers are small, designed to be held by a test fixture or between the thumb and forefinger, and have small circuit assemblies that carry the actual probe tips and their isolation/coupling networks. These isolation/coupling networks are often implemented with small surface mount components carried on a substrate. Owing to their small size these probe tip assemblies are delicate, yet must be robust enough to resist the force needed to penetrate a solder mask or other protective coating, and should offer easily varied probe tip spacing and compliant probe tip contact despite variations in angular position relative tot he location being probed. Techniques to accomplish this are the (“mechanical”) subject matter of the incorporated Patent Applications filed by Cannon, and by Cannon et al.

Bandwidth continues to increase, bringing with it a need to further refine the micro-browser used with the replication amplifier. There is a need for a micro-browser that is usable to twenty or more Giga hertz. The probe tip assemblies for such a micro-browser will be smaller than anything previously in use, but still must be physically strong enough to resist the forces that may reasonably be expected during normal use. The techniques disclosed in Cannon and in Cannon, et al. use surface mount components that are soldered to a substrate, say of FR4. The resulting probe tip assembly is simply too big for use at 20 GHz and beyond. We need to re-invent its mechanical properties, to remove its attending (and limiting) electrical side effects. What to do?

### SUMMARY OF THE INVENTION

Probe tip assemblies for a micro-browser are reduced in size in a first embodiment by using small surface mount components in an isolation/coupling network that may include a parallel RC combination in series with a damping resistor. These surface mount components are soldered directly to one another without the use of a substrate. A pointed contact tip is soldered directly to one end of the surface mount components, and at the other end of those components is soldered the center conductor of a coaxial transmission line leading to a replication amplifier. A portion of the isolation/coupling network is enclosed within a supporting conductive shield that is also soldered to the outer conductive shield of the coaxial transmission line. The isolation/coupling network is supported against the coaxial cable's center conductor and its connection thereto strain relieved by potting the isolation/coupling network into the conductive shield. The result is a unitized probe tip assembly. A pair of unitized probe tip assemblies may be mechanically attached to a respective pair of stationary and rotating rods that are themselves carried by a sleeve located within a grip. In operation, the probe tip for the rotating rod may be pressed against one end of an electrical signal of interest, while the grip and its sleeve are rotated to produce an eccentric motion in the stationary rod and its probe tip. This eccentric motion allows variation in probe tip spacing. An axial resilience in the rotatable rod allows for modest subsequent variation in probe position without loss of electrical contact. Either by a bend in the stationary rod or by having the axes of unbent rods converge, adjacent corners of the supporting conductive shields (and that are nearest pointed contacts) are in mechanical, and thus also electrical, contact. That is, these corners are grounded together at a location that is as close as practical to the electrical signal being probed, and remain so despite changes in probe tip spacing (i.e., spacing between the pointed contacts). This helps minimize a loop area that is important in determining the upper frequency limit of the probe's operation.

The rods and/or the lengths of coaxial transmission line may be of “memory metal” such as Nitinol to allow nondestructive deformation under excessive applied force. The memory metal may be of either the ‘superelastic’ variety that automatically reforms itself immediately or of the ‘shape memory’ variety that reforms itself upon the application of mild heat, such as immersion in hot water. The coaxial transmission line affixed to the supporting shield may be a semi-rigid micro-coax (of regular metal or of memory metal) that transitions into a flexible coaxial cable after passing through slots in the grip.

In an alternate embodiment the isolation/coupling network may be a shaft of resistive diamond having a sharp tip at one end where it has a low bulk resistance the functions as a series damping resistance, which shaft also has toward the other end a much higher bulk resistance that functions as an isolation resistance that is also shunted by a coupling capacitance formed of a conductive pattern printed on the outside of the region of higher bulk resistance.

### BRIEF DESCRIPTION OF THE DRAWINGS

FIG. 1 is a perspective view of a prior art hand held micro-browser for use with a digital oscilloscope;

FIG. 2 is an enlarged perspective view of the prior art micro-browser of FIG. 1;

FIG. 3 is an exploded perspective view of the probe tip, circuit board, rod, sleeve and grip portions of the prior art micro-browser of FIGS. 1 and 2;

FIG. 4 is a simplified schematic of an improved pole-zero cancellation active differential probe having unitized probe tip assemblies;

FIG. 5 is a perspective and partially exploded view of a first preferred embodiment of the unitized probe tip assembly of FIG. 4;

FIG. 6 is a perspective view of a second preferred embodiment that is of mirror image handedness of the unitized probe tip assembly of FIG. 4;

FIG. 7 is a perspective view of a portion of a micro-browser of the sort shown in FIGS. 2 and 3 but incorporating the unified probe tip assemblies of FIG. 5, and illustrating the probe tips in a position of minimal spacing therebetween;

FIG. 8 is a perspective view similar to that of FIG. 7, but with the probe tips in a position of intermediate spacing therebetween;

FIG. 9 is a perspective view similar to that of FIG. 7, but with the probe tips in a position of maximal spacing therebetween;

FIG. 10 is a perspective view of a micro-browser after the manner of FIG. 3 but incorporating the unitized probe tip technique shown in FIGS. 4-9; and

FIGS. 11A, 11B and 11C are simplified side and front and rear views, respectively, of an alternate embodiment of the unitized probe tip assembly of FIG. 4, where the isolation/coupling network is a shaft of resistive diamond having a sharp tip and with varied bulk resistance and a printed capacitance.

### DESCRIPTION OF A PREFERRED EMBODIMENT

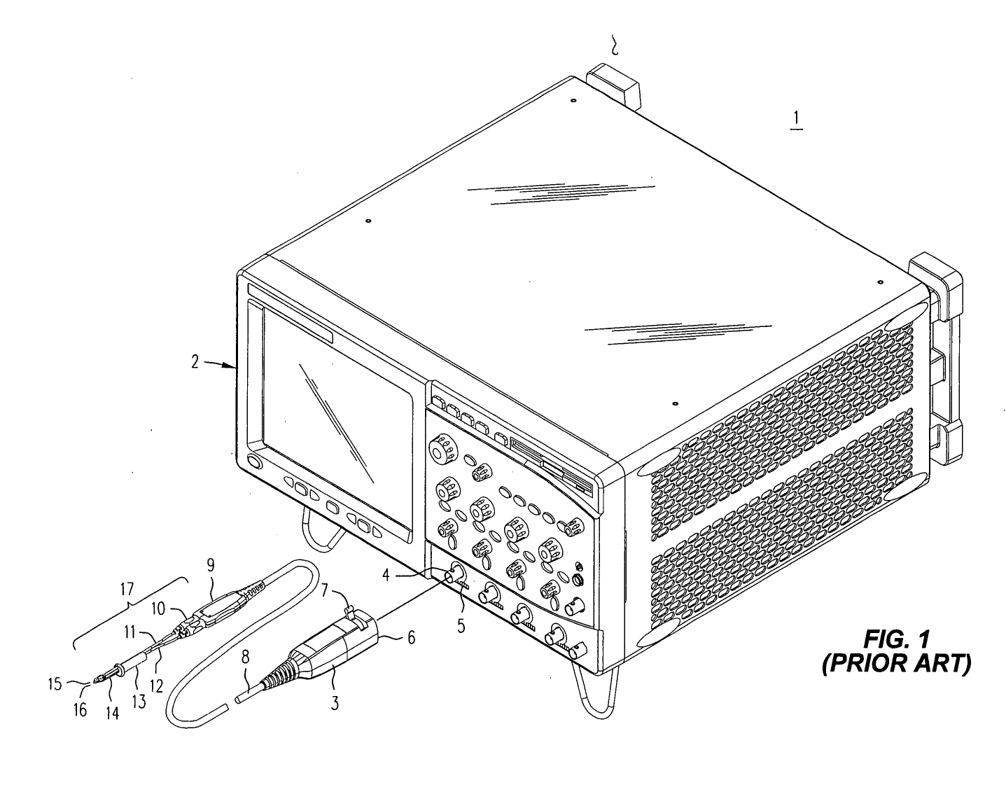

The following is an abridged version of the description of FIGS. 1-3 from the incorporated UNBREAKABLE MICRO-BROWSER. We include it here to set forth the immediate environment into which we shall introduce and describe the invention.

Refer now to FIG. 1, wherein is shown a front perspective view of an electronic instrument 2, such as a digital oscilloscope, having one or more front panel connectors 4 that each receive a push-lock BNC connector 3, say, in support of operation with active probes. In a manner known in the prior art, the push-lock BNC probe housing is installed simply by lining it up and then pushing it toward the 'scope. When the push-lock connector 3 is in place, not only is a BNC connection established to connector 4, but a row of spring loaded pins 6 (not visible) on the front panel of the housing for the push-lock assembly engages a row 5 of contacts beneath the connector 4. To remove the push-lock connector the operator pushes on lever or tab 7 with a thumb or a finger, while pulling the assembly away from the 'scope. A main cable 8 carries both power to, and signal information from, an amplifier pod 9 which contains high frequency replication amplifiers.

A pair of short flexible transmission lines (11, 12) couple a prior art micro-browser 17 to the amplifier pod 9 via a pair of coaxial connector (10). The micro-browser includes a grip 13 suitable for being held between the thumb and forefinger. A sleeve 14 is carried by the grip, and supports a pair of movable small circuit boards each having a probe tip (contact points 15 and 16). The small circuit boards may be of glass epoxy (FR4) or of ceramic material.

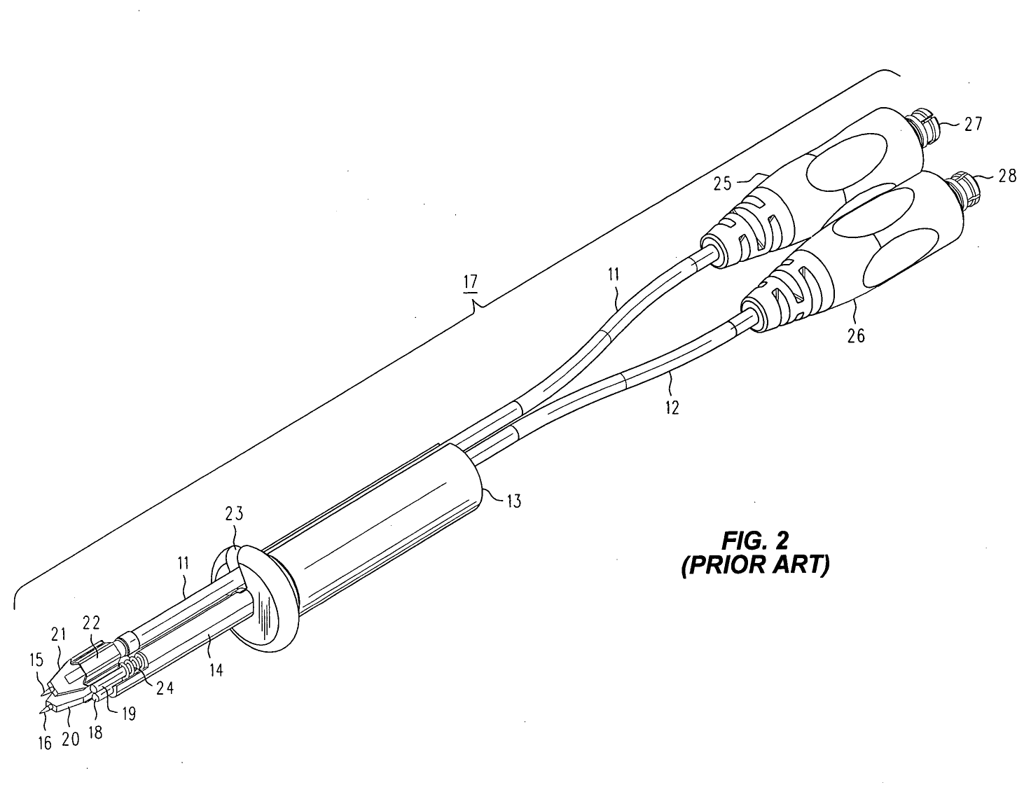

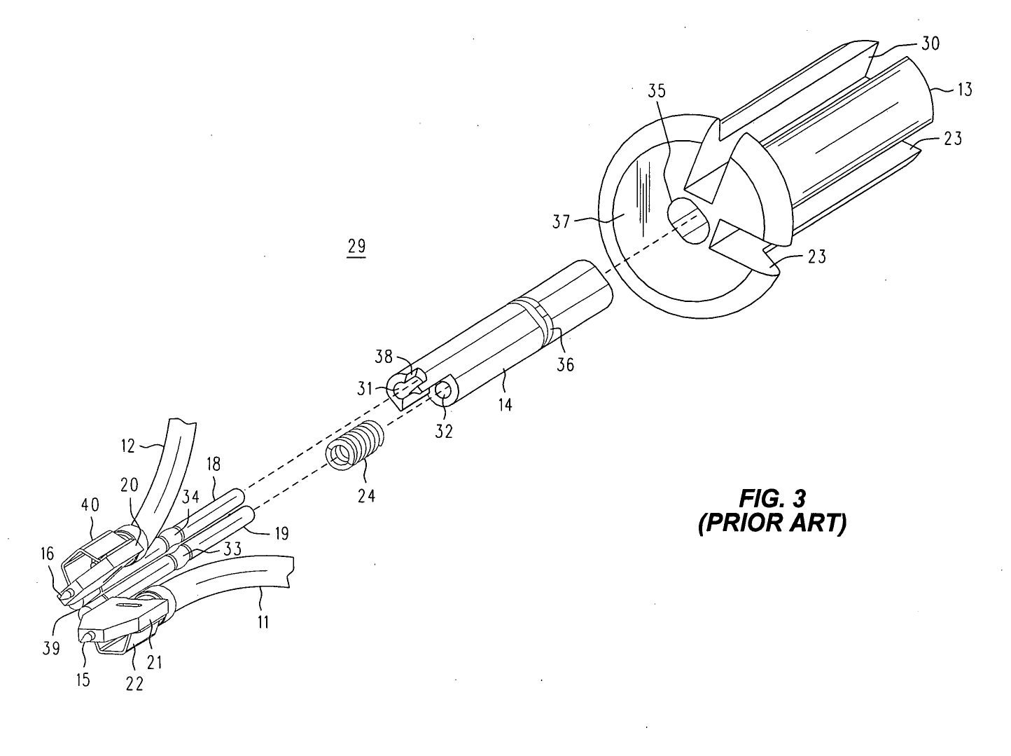

Refer now to FIG. 2, wherein is shown an enlarged perspective view of the prior art micro-browser 17 of FIG. 1. this view shows a grip (13) which has received a sleeve (14). Although better shown in FIG. 3, the sleeve 14 has two parallel bores that carry rods 18 and 19 that may be of memory metal, such as Nitinol. A memory metal is preferred so as to “gorilla proof” the micro-browser against the application of excessive force. The rods 18 and 19 are sized to deform before the probe ends undergo damage. The ends of those rods are each soldered to the side of a respective small circuit board, 20 and 21. Each small circuit board carries a coupling network which is shielded by a conductive cover (or shield) of which only one (22) is thereof is visible in FIG. 2. Each of the small circuit boards has a small sharp probe tip or pointed contact (15, 16). These probe tips are electrically connected to their respective associated coupling networks, which are in turn coupled to associated coaxial cables (11, 12) that may also function as transmission lines. A slot 23 in the grip carries cable 11, while a second slot (not visible in FIG. 2) carries the other cable 12.

(Rotatable) rod 19 and its circuit board 21 are free to rotate at least 180° about the axis of the rod. A spring 24 fits over rod 19 and provides resilient resistance to compression between circuit board 21 and the sleeve 14 in a direction along the axis of rod 19. (Stationary) rod 18 and its circuit board 20 are prevented from rotating by a notch (not visible) in the end of the sleeve and that engages the end of the small circuit board 20. The terms “stationary” and “rotatable” are relative to the sleeve/grip combination.

The two cables 11 and 12 have respective strain relieving boots 25 and 26 that also carry suitable coaxial connectors 27 and 28 that plug into corresponding connectors in the amplifier pod 9.

Referring now to FIG. 3, we see an exploded perspective view 29 of most of the stuff in FIG. 2. The parts have been rotated about 90° clockwise in FIG. 3, so that slot 30 for cable 12 is visible. Due to the exploded nature of the drawing, the bores 31 and 32 in the sleeve 14 are visible. Bore 31 receives rod 18, while bore 32 receives rod 19. Note bends 33 and 34 in the rods 19 and 18, respectively. These slight bends (hump-shaped, or otherwise) cause the friction that retains the rods in their bores.

Also visible in the figure is oval shaped bore 35 in the grip 13. It receives the sleeve 14 until stop 36 limits the penetration of the sleeve 14 into the bore 35 by interference with surface 37. Bore 35 may have a slight taper to provide a minor amount of interference with sleeve 14, and thus retain it in the bore by friction. Note that the oval shape of the bore 35 cooperates with a corresponding oval exterior of the sleeve to positively communicate any rotation of the grip to the sleeve.

A notch 38 is visible in FIG. 2 adjacent the aperture of the bore 31. What this does is engage the back side of the small circuit board 20, and cause it to be stationary, or non-rotating about the axis of its bore within the sleeve. It is from this that the rod 18 becomes “stationary” even if it is later observed to be moving or rotating because the sleeve/grip combination is being moved or rotated.

Also visible in FIG. 3 is that the distal ends of the two rods 18 and 19 touch at location 39, despite the majority of the rods being parallel elsewhere along the length of their axes. This touching is also electrical contact and may be accomplished by a slight bend in the stationary rod 18 toward the rotatable rod and at the location where the stationary rod 18 is attached to the board 20. Thus, no matter what the rotation of rotatable rod 19, the two rods continue to touch. This is of significance to the shields 22 and 40, each of which are soldered to a ground supplied by its associated coaxial cable (11 and 12). The idea is to get those two grounds tied together as close as possible to their probe tips.

In an alternate prior art embodiment both of the rods 18 and 19 are straight (no bends to cause touching, but they still have humps 33 and 34), have axes that are coplanar, but convergent such that the ends of the rods near the circuit boards 20 and 21 are touching. This condition is obtained by having the axes of the bores 31 and 32 in the sleeve 14 be coplanar, but convergent along the direction toward the probe tips. This coplanar but convergent axes embodiment is our preferred starting point for the description that follows, although it will be abundantly clear that the invention may be practiced with the bent stationary rod in an otherwise parallel axes embodiment, as well.

In operation, the spring loaded rotatable probe tip 15 is pressed against an intended location. This is done by rotating the grip 13 (and thus the entire micro-browser 17) before any contact is made. Once contact is made with the rotatable probe tip 15, (and assuming that there is not yet contact by the other, stationary, probe tip 16) further rotation of the grip 13 also rotates the sleeve 14, which in turn causes an eccentric rotation of the stationary probe tip that varies the spacing between the two probe tips 15 and 16. (This creates the appearance of the stationary tip moving, but only because it is staying put relative to the moving sleeve/grip. By the same token, the rotatable rod/tip seems to stay put, but only it is stuck into the assembly to be measured, and is free to rotate within the moving sleeve/grip. The terms ‘rotating’ and ‘stationary’ have to be relative to something, and we choose top make them relative to the sleeve/grip.)

By moving the grip 13 in circular path (orbiting) without rotation the general orientation of the stationary probe tip 16 relative to the other (15) can be controlled—think up, down, left and right here, and not so much about distance, although distance will be affected. When both the correct spacing and the correct general orientation are achieved by a combination of orbiting and rotation, the stationary probe tip 15 will then be positioned above the other location to be probed. An angular displacement of the axis of the grip 13 within the plane containing that axis (a “tilting” of the entire micro-browser without further rotation or orbiting) will lower the stationary probe tip onto the target location. The resilience of the moveable probe tip's spring 24 will enable that probe tip (15) to continue making contact as the stationary probe tip is the also firmly pressed into its location with sufficient force to make reliable electrical contact. Once contact is made with both probe tips a reasonable amount of tilting and “rocking” (motion in a direction orthogonal to tilting) can be tolerated without either probe tip coming off (losing contact), provided the spring 24 remains at least slightly compressed in response to force from the operator.

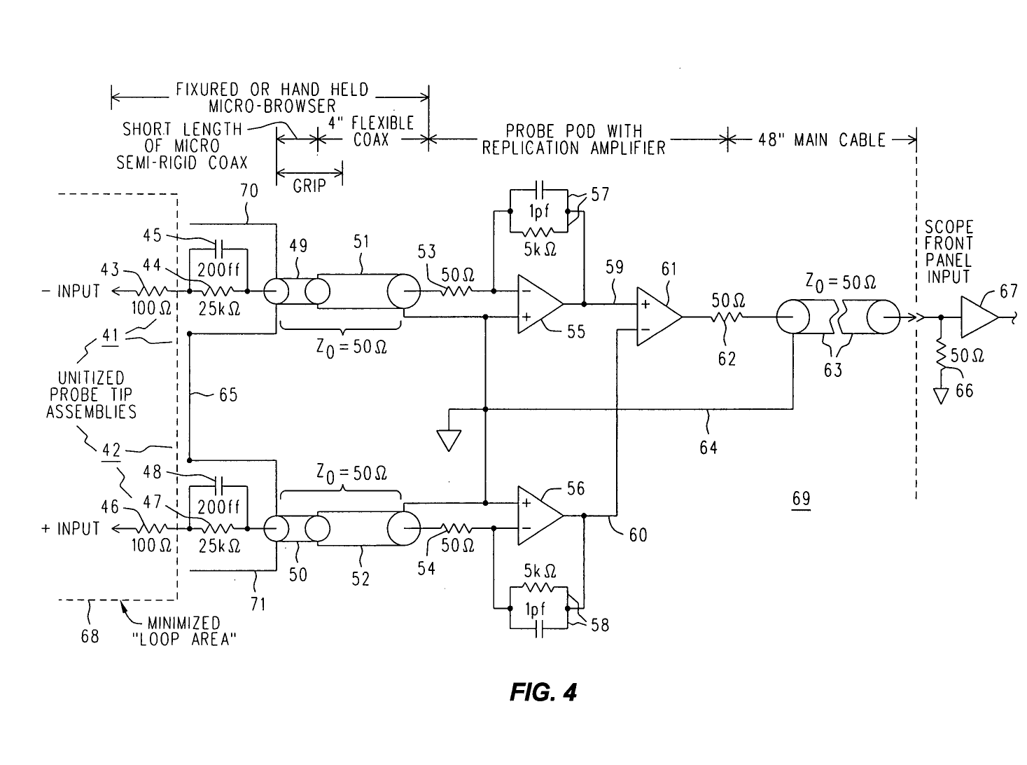

Refer now to FIG. 4, wherein is shown a simplified schematic 69 describing the combination of unitized probe tip assemblies in use with replication amplifiers and the pole-zero cancellation technique for a high frequency differential active probe. To begin, there are two unitized probe tip assemblies, 41 and 42, that each include an isolation/coupling network. The assemblies 41 and 42 are identical to each other, and their manner of mechanical construction (i.e., why we describe them as being ‘unitized’) will be discussed in connection with later figures.

The isolation/coupling networks each include a series damping resistor (43, 46) whose value may be in the vicinity of 100 Ω. One end of the series damping resistor is the actual signal input, and is the location of a sharp contact point that serves as the actual physical probe tip. The other end of each damping resistor is connected to one end of a respective parallel RC combination (44/45 for 43 in 41 & 47/48 for 46 in 42) that may be 25 KΩ in parallel with 200ff. The other end of each parallel RC combination is coupled into a short length (say, and inch or so) of very small (0.020″ outside diameter!) semi-rigid coaxial cable (49, 50) of 50 Ω characteristic impedance. Such small (and even smaller!) semi-rigid coaxial cable (which is NOT of a memory metal such as Nitinol) can be obtained from, among other vendors, MICROSTOCK, INC. of West Point, Pa. (215-699-0355 or www.microstock-inc.com).

It will be appreciated that, owing to the replication amplifier arrangement (especially 61) described in due course, unitized probe tip assembly 41 functions as a minus (−) portion of a differential input, while unitized probe tip assembly 42 functions as the plus (+) portion of that differential input.

It will be noted that the schematic 69 indicates that the last, or “interior,” portion of the isolation/coupling networks is surrounded by a ground shield (70, 71). How this is achieved mechanically and the role played in that outcome by the semi-rigid coaxial cables 49 and 50 will become apparent in due course. Meanwhile, it will be appreciated that the circuit region enclosed by the dotted lines 68 is one that offers special mischief in connection with high frequency measurements. It functions as a loop into which signals can be coupled. Such coupling can both load the circuit being measured (by coupling into its near field) and induce spurious signals that are not entirely or correctly removed through common mode rejection. To minimize these ill effects we desire to keep the area of this loop as small as possible. The area of the loop is not constant, as one dimension is set by the variable spacing between the contact points. The other dimension is set by the physical length of the components NOT shielded by the ground shields 70 and 71. We have made that distance as short as practical (if the shields 70 and 71 were made longer there is a substantial risk of accidentally shorting the measured signal to ground . . . ).

It will be observed from the schematic 69 that the small semi-rigid coax (49, 50) transitions into respective lengths (51, 52) of larger flexible coax that is also of 50 Ω characteristic impedance. At the frequencies of interest (up to 20 GHz, or so) this transition needs to done with some care. It might be accomplished with a good grade of RF connector (e.g., APC 3.5) or with a precision ‘barrel’-style transition connection that is soldered to both the semi-rigid and flexible cables. The flexible cable is needed to allow the micro-browser to be readily moved with respect to the probe pod, and needs to be large enough to exhibit adequate durability. Larger coax is also less lossy. It is preferred that the transitions between the two types of coax occur just after the semi-rigid coax leaves the rear of the grip.

To continue, the probed differential signal now reaches 50 Ω termination resistors 53 and 54, which are in series with virtual grounds for respective amplifiers 55 and 56. Each ofthose amplifiers has a respective feedback network (57 for 55 & 58 for 56) that provides the pole that cancels the zero formed by the lengths of transmission line (51, 52) in conjunction with the effects of the respective isolation/coupling networks (41, 42). It will be appreciated that each of the (−) and (+) inputs has its own cancellation of a zero by a pole.

To further continue, the outputs 59 and 60 from the amplifiers 55 and 56 are combined in a differential amplifier 61, whose single ended output drives a 50 Ω matching resistor 62 in series with the center conductor of a main 50 Ω coaxial cable 63 that leads to the front panel input (for some input channel) of the DSO. There the replicated signal is applied to a 50 Ω termination 66 and an input amplifier 67. It will be appreciated that the portions of the schematic 69 that deal with the circuitry between flexible coax 51 and 52 and the ‘scope’s input amplifier 67 are conventional, save perhaps for the upper frequency limit of 20 GHz, and that additional details of how that stuff operates my be found in the incorporated Patents to Rush and Eskeldson, et al.

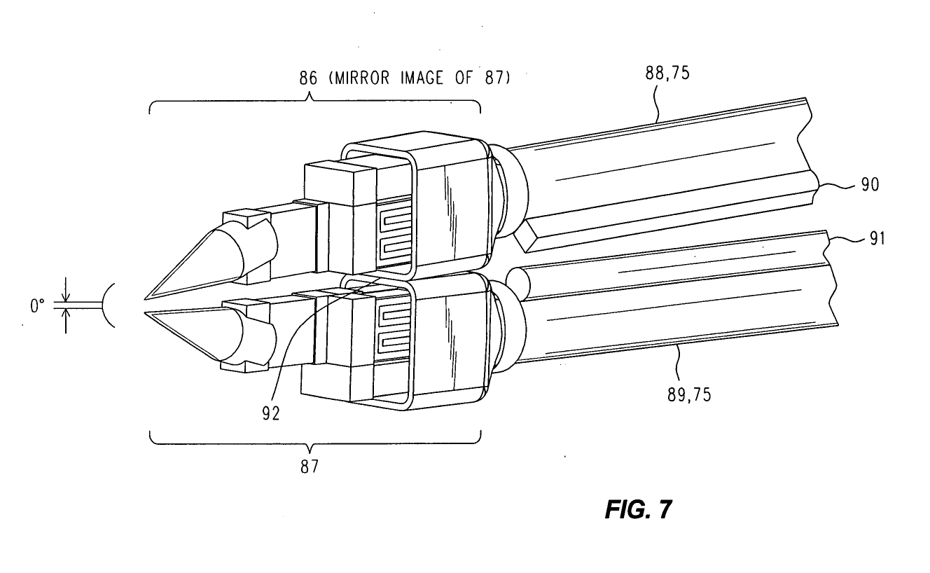

Before leaving FIG. 4, however, there is one last topic that deserves some mention, and it concerns this business of minimizing loop area. It is not sufficient that the two shields 70 and 71 be at ground in a DC sense (although that DC condition does obtain). It is also important that they be grounded to each other without the RF path for that connection going through any connection going through any other components (to do so would extend a dimension of the loop and increase its area—the opposite of what is desired). This connection between shields 70 and 71 is, of course, indicated by line (‘conductor’) 65. It represents an actual shield-to-shield (70 to 71) ohmic contact, and as such is a conductor of ‘zero’ length. How it is done mechanically will be shown in connection with FIGS. 7, 8 and 9. It (connection 65) corresponds to the point of contact 39 in FIG. 3.

Now, it will be noted that ‘conductor’ 65 is at ground because the outer shields of coaxial cables 49/51 and 50/52 are themselves at ground by virtue of a connection 64 to the grounded outer shield of the main coaxial cable 63. There is noting sinister in this, although connection 64 is not part of a transmission line structure, careful attention to the physical layout of the RF paths in the replication amplifier is indicated. Ground planes are useful in this connection (please pardon the horrible pun).

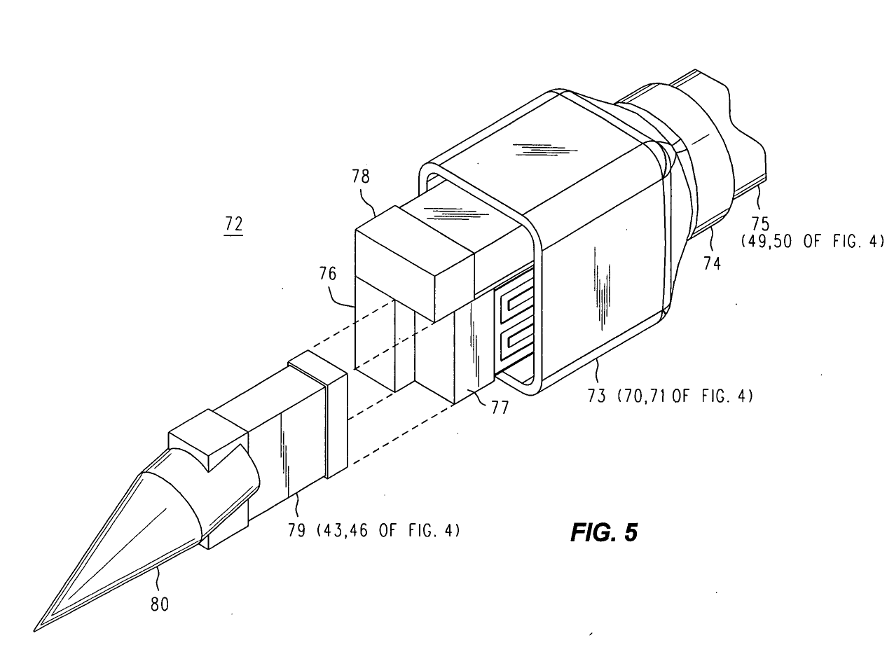

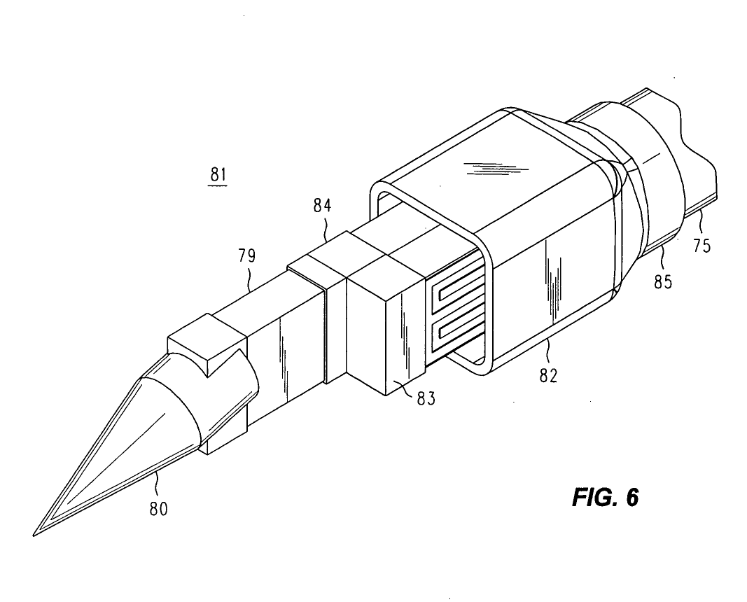

Refer now to FIG. 5, wherein is depicted a partially exploded perspective view of a unitized probe tip that could be either of the unitized probe tips discussed in connection with FIG. 4. (However, a brief look ahead at FIGS. 7-10 reveals that, in one preferred embodiment anyway, the unitized probe tip assemblies are used in left/right pairs, each member of which is the mirror image of the other. It would not, in principle, have to be that way, and our reason for doing it here is that it provides an offset that increases the range of the variable span between the contact points. Hence, what we show in FIG. 5—and also in FIG. 6—should be understood as one half of a mirror image pair. In particular, arrangement 72 of FIG. 5 will be appreciated as corresponding to unitized probe tip 87 of FIG. 7.)

A good place to begin is with the semi-rigid micro coax 75, which corresponds to either length of coax 49 or 50 in FIG. 4. Its exposed outer shield enters the inside surface of a collar 74 that is part of a formed metal shield 73 that corresponds to an instance of either of 70 ro 71 in FIG. 4. Formed metal shield 73 may be of plated brass. The outer shield of the coax 75 may be soldered to the collar 74.

Formed metal shield 73 surrounds, essentially on all but one surface, an assemblage of parts that make up the isolation/coupling network. The essentially surrounded parts are, in the embodiment of FIG. 5, a 50KΩ surface mount resistor 76 that is physically and electrically in parallel with a laser trimmed (nominally) 200ff surface mount coupling capacitor 77, both of which are physically and electrically in parallel with another 50KΩ surface mount resistor 78. The two paralleled 50 KΩ resistors 76 and 78 form an instance of one of the 25 KΩ isolation resistors 44 or 47 that are shown in FIG. 4. The purpose of having two resistors 76 and 78, instead of just one, is to increase the mechanical strength of the assemblage. (Notice how capacitor 77 is slightly recessed with respect to the ends of resistors 76 and 78 to form a partial socket that overlaps on two sides the solder joints for resistor 79. It will be appreciated that other such “staggered” arrangements are possible.) At this point it will be appreciated that one of resistors 76 and 78 could be 25 KΩ, while the other is some electrically benign value that does not significantly affect the parallel combination, such as 10 MΩ, or, they could both be 50 KΩ, as earlier described.

Soldered to the assemblage of surface mount parts 76, 77 and 78 is another surface mount resistor 79, which corresponds to one of the damping resistors 43 or 46 in FIG. 4. In FIG. 5, resistor 79 is shown as exploded away from the assemblage, and as otherwise being abutted to capacitor 77. Electrically, it makes little if any difference where resistor abuts the assemblage, and various other arrangements are possible. So for example, resistors 76 and 78 might have ends that are flush with one another while the end of capacitor 77 is recessed as shown. Locating resistor 79 so that it physically bridges the joints between parts 76 and 77 may also provide an increase in the strength of the assembled surface mount parts. However, the location shown has the advantage of an increase in strength while also maximizing the amount of variation available for the user-adjustable spacing of the probe tips (contact points) 80 that are soldered to the far ends of the damping resistors 79 (only one such contact point is shown in the figure).

While on the subject of the contact point 80, we should point out that it ought to be very sharp as such things go. The unitized probe assembly 72 of which it is a part is rather small (it would more or less fit inside this 0), and one of the reasons for using shape memory wire for the stationary and rotating rods (to which the unitized probe tips will be attached) is to limit the applied force to non-destructive amounts (i.e., to ‘gorilla proof’ the probe). Some definite amount of force is, however, required, if the contact point is to pierce or penetrate a solder mask or other protective coating over the circuit element to be probed. The sharper the contact point is, the lesser the force required to make electrical contact. We prefer our contact to have a ‘flat spot’ on the end that is only 0.001″ to 0.0005″ in diameter, which makes itpretty sharp in comparison to our larger prior art versions, which have a flat spot of about 0.002″ in diameter. We find that grinding the tips produces a sharper point than turning does. The contact point itself can be of beryllium copper, ground and coated with a layer of conductive diamond (for wear resistance and to allow increased loading without dulling the point).

However, it should not be assumed that sharp conical contact points are the only possible our useful types of contact points. It could also be a crown shaped affair with several diverging points, a sharp chisel point, a yoke or even a concave socket intended to fit over a post expected to be a part of the circuit being measured.

The surface mount components used for 76-79 can be of the 0402 standard style (0.040″×0.020″×0.010″). Alternatively, those surface mount parts can be of the even smaller 0201 standard style. It will be noted that these surface mount components are standard off the shelf items.

The small size of the surface mount components means that the conductive shield 73 is also small. For the embodiment shown in FIG. 5, it is about 0.038″ in height, 0.031″ in width and about 0.052″ long. It has a wall thickness of just a few thousandths of an inch (say, 0.005″), and may be made by forming a short length of brass or copper tubing over a mandrel. The formed shield may then be trimmed and plated for appearance and resistance to oxidation. Note the collar section 74, which is soldered to the exposed outer shield of the tiny semi-rigid coaxial cable 75.

The center conductor (not shown) of the coax 75 is, of course, soldered to the distal end of the assemblage of surface mount parts 76-79 and their contact point 80. That is, soldered to the face formed by resistors 76 and 78 that is (after final assembly) inside the conductive shield 73. This may be accomplished by first engaging the collar 74 over the coax 75 and sliding the conductive shield a little way along the prepared coax 75 to expose the end with its tinned center conductor. The assemblage is then soldered to the center conductor, and afterward the conductive shield slid back until it covers the desired amount of the assemblage, but not so far back that it shorts against the surface that the center conductor was soldered to. Then the collar 74 is soldered to the outer shield of the coax 75.

A potting compound (e.g., epoxy) may then be dripped into the space between the inner surface of the conductive shield 73 and the surface mount components 76-78. It may be advisable to allow the epoxy or other adhesive to first outgas trapped air bubbles by exposure to a vacuum. Similarly, it may also be advisable to apply the adhesive or potting compound while in a vacuum, but then let it cure while exposed to atmospheric or greater pressure, the better to force the stuff into crevices that its surface tension would otherwise bridge.

An alternate manner of constructing a unitized probe tip 81 with off the shelf surface mount components is shown in FIG. 6. This embodiment is similar to that of FIG. 5, save that it has only one resistor (84) in parallel with the laser trimmed capacitor (83). As before, a damping resistor 79 is soldered to the face of the assemblage (83, 84). A contact point 80 is soldered to the end of the damping resistor 79. In this embodiment the conductive shield 82 is a square about 0.031″ on a side by about 0.052″ long, and as before, its collar 85 is soldered to the outer shield of the coax 75, as previously explained in connection with FIG. 5. For the sake of illustrating different possibilities, the embodiment shown in FIG. 6 does not use any of the previously mentioned staggering of parts to produce overlapped solder joints, and corresponds (in left/right terms) to the unitized probe tip assembly 86 of FIG. 7.

It will further be appreciated that the embodiments of FIGS. 5 and 6 (and implication, those of FIGS. 7-10) need not necessarily be made using surface mount components. Other resistive and capacitive parts having the requisite small size, suitable terminal attributes and strength can be used.

Refer now to FIGS. 7, 8 and 9. These figures show, in various degrees of rotation that produce increasing spacing between the contact points, the manner in which left/right pairs of the embodiment of FIG. 5 can be assembled to obtain a pole-zero cancellation active probe that is a micro-browser similar to those of FIGS. 1 and 2, but smaller, having minimal loop area, and usable up to frequencies in the vicinity of 20 GHz.

Without further ado, then, FIG. 7 illustrates a left/right pair of unitized probe tips after the fashion of FIGS. 4 and 5, depicted in a condition of minimal spacing between the contact points. Item 86 is a unitized probe tip assembly that is similar to that (72) shown in FIG. 5, save that it is a mirror image and that one of the coupling resistors is recessed, while the capacitor is not. Item 87 is a second instance of a unitized probe tip assembly similar to that shown in FIG. 5, but is also a mirror image of item 86. In the interests of clarity, any potting compound has been omitted from this front perspective view. As explained in the incorporated “COMPLIANT MICRO-BROWSER FOR A HAND HELD PROBE” the distance between the contact points varies as a function of eccentric motion produced by orbiting a stationary probe tip not yet in contact about a rotatable probe tip that is in contact with the circuit to be measured. The orbiting in the incorporated disclosure corresponds to a revolution of about 180°. In the present embodiment the orbiting motion produces rotational displacement corresponding to about 90°. FIG. 7 shows the situation at one end of that 90° range, which we shall call 0°, and which produces minimum spacing between the contact points.

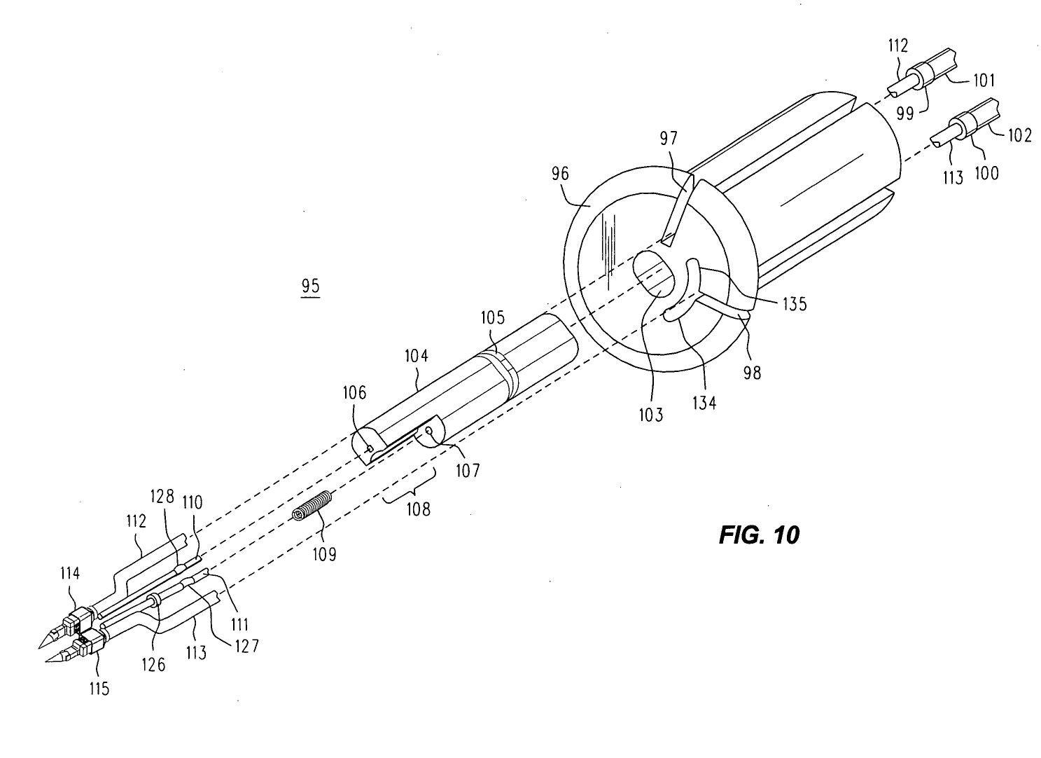

The above-mentioned rotation is about the axis of rod and 91, which is one of two rods 90 and 91 that are soldered to the outer shields of the semi-rigid coaxial cables 88 and 89, respectively. It is preferred that, after the fashion taught in “COMPLIANT MICRO-BROWSER FOR A HAND HELD PROBE,” those axes of rods 90 and 91 lie in a common plane but are not parallel; they converge as the proceed toward the contact points. It is also possible that the convergence of the rods 90 and 91 results from a bend in the stationary rod 90 located between the conductive shield and whatever carries the rod (sleeve 104 of FIG. 10), also as taught in “COMPLIANT MICRO-BROWSER FOR A HAND HELD PROBE.” In any event, the convergence of the axes of the rods 90 and 91 causes the conductive shields of the unitized probe tip assemblies to contact each other both mechanically and electrically along edge 92 when the amount of orbital motion is 0°. This electrical contact is what minimizes the aforementioned loop area (68 in FIG. 4) and corresponds to the “zero length” conductor 65 in FIG. 4.

Because of the small size of the unitized probe tip assemblies shown in FIG. 7, it is preferred that the rods 90 and 91 limit operator applied forces to safe levels by bending when those levels are exceeded. That in itself is fine as far as it goes, but they also need to ‘unbend’ after the dangerous episode is over. To provides this handy functionality it is preferred that the rods 90 and 91 be of a shape memory metal, such as Nitinol as is described in the incorporated UNBREAKABLE MICRO-BROWSER.

It will be noted that rod 90 is square, while rod 91 is round. The square rod is a device to accomplish the “stationary” attribute of its associated probe tip. To look ahead, it goes into a square bore (106) in a sleeve (104 of FIG. 10), and corresponds to how the notch 38 of FIG. 3 keeps substrate 20 from rotating (i.e, ‘stationary’) about its support rod 18. It will be appreciated that other cross sections or shapes beside square can cause the necessary slidable entry into the sleeve while preventing rotation. In that same connection, it will be appreciated that rod 91 is round and that it goes into a round bore in the sleeve. This allows it to be the ‘rotatable’ rod (which is why its associated unitized probe tip assembly is ‘rotatable’).

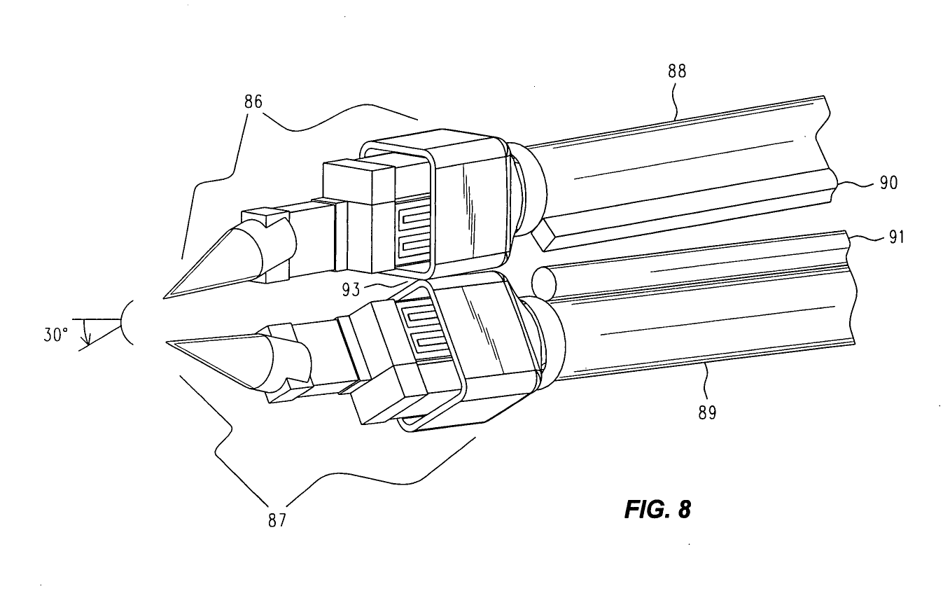

Now consider FIG. 8. In this view rotatable unitized probe tip assembly 87 has been rotated approximately 30° about the axis of rod 91. Note that the point of contact between the conductive shields has moved to location 93. The location of 93 is slightly into the rounded corner region; if the amount of rotation were 45° then the location of contact would be at the middle of the corners. THAT location (not actually indicated) is essentially where the axes of the two rods 90 and 91 converge. In any event, it will be noted that the spacing between the contact points has increased, compared to the 0° case of FIG. 7.

The location of convergence for the rods 90 and 91 is very close to that indicated by reference number 93 in FIG. 8. Each of the corners proximate location 93 has the same radius, and each of those radii originates on an extension of the axis for the associated rod 90 or 91. To create good mechanical and electrical contact, it is desirable that there be interference that is accommodated by a resilient bending of the rods 90 and 91. To get this interference the axes of the rods 90 and 91 might be slightly too close together for the size of the conductive shields, the conductive shields themselves might be ‘slightly too large’ or the location where the axes of the rods converge can be located such that it occurs sooner rather than later in the direction of travel that is from the grip toward the probe tips.

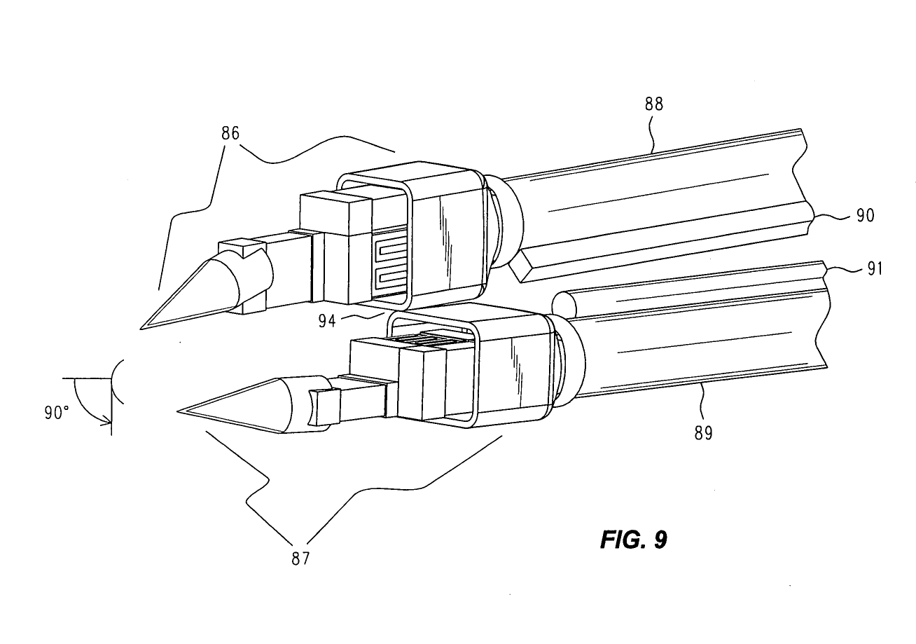

In FIG. 9 the amount of rotation is 90°, and the degree of spacing between the contact point has increased even more. The location of contact between the conductive shields remains on the corners, as shown by reference number 94. More than 90° of rotation is possible, up to 180°, where again two sides will be in contact, after the fashion shown in FIG. 7. However, for the component/contact point arrangements shown, maximal spacing occurs only a little after 90° and thereafter actually decreases somewhat toward 180°.

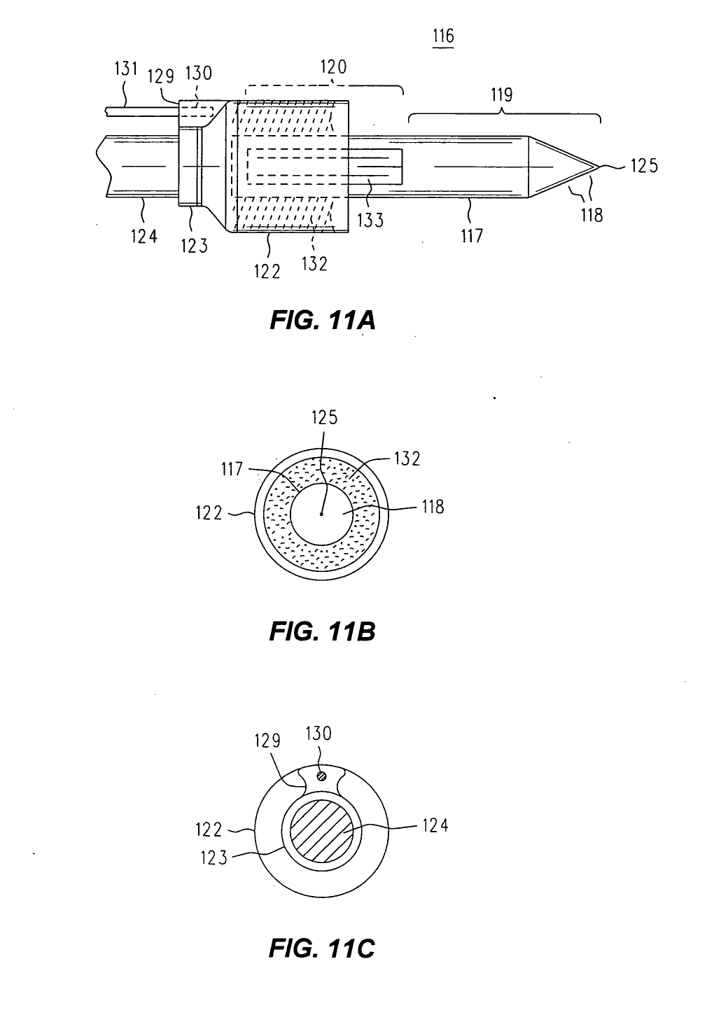

Although we have shown the manner of attaching the rods 90 and 91 to the semi-rigid coaxial cables 88 and 89, respectively, as soldering to the outer shields thereof, it will be appreciated that it is also possible to the rods directly, or through an intervening part such as a bracket or a gusset, to the conductive shields themselves. As another example, a conductive shield could have a raised mounting collar (not shown) with a hole in it to receive its rod, located adjacent the existing collar 74 on the end of the shield away from where the probe tip extends, and centered over the axis of the rod. Because the diameter of the rod is small, the wall thickness of this mounting collar combined with its depth (the amount it extends out to or beyond collar 74) such a mounting collar would afford an excellent way of attaching the rod to the conductive shield. (See item 129 in FIGS. 11A and 11C for a very similar approach in a slightly different embodiment.)

Referring now to FIG. 10, how all the afore-mentioned elements are combined can be seen in a front perspective exploded view. Beginning at the lower left corner, we see the two unitized probe tip assemblies, 114 and 115. Their respective lengths of semi-rigid coaxial cable 112 and 113 are each seen to have (after being soldered to rods 110 and 111) S-curves that move their axes out to line up (as shown by the dotted lines) with respective slots 97 and 98 in a grip 96. Slots 97 and 98 are fairly narrow, and are sized to be just wide enough to comfortably receive the semi-rigid coaxial cables 112 and 113, respectively. Slot 97 is a simple slot, since the length of semi-rigid coaxial cable 112 it receives is attached to the non-rotating (square) rod 110, and thus does not move. Slot 98, on the other hand, must accommodate the rotation of rod 111. Accordingly, slot 98 includes curved sections 134 and 135 that allow passage for semi-rigid cable 113 as rod 111 rotates.

After the semi-rigid cables 112 and 113 pass through their slots to the far end of the grip 96 they encounter respective barrel connectors 99 and 100 that are soldered-in-place transitions to the larger flexible coaxial cables 101 and 102 (corresponding to cables 11 and 12 of FIG. 2 and to 51 and 52 of FIG. 4).

A sleeve 104 of oval cross section enters an oval bore 103 that may be slightly tapered to retain the sleeve. The sleeve 104 enters bore 103 until a shoulder or stop 105 encounters the face of the grip at the entrance of the bore 103. Thus, rotation of the grip 96 is communicated to the sleeve 104, and the sleeve is retained in the grip.

A bore 106 of square cross section in sleeve 104 receives the square rod 110 that carries the stationary unitized probe tip assembly 114. A slight bend 128 provides the friction that retains rod 110 in its bore 106.

A round bore 107 in sleeve 104 receives the round rod 111 that carries the rotatable unitized probe tip assembly 115. A slight bend 127 provides the friction that retains rod 111 in its bore 107. Note that bore 107 is located on a shoulder formed by recess 108 that provides space for spring 109. Spring 109 slips over rod 111 to provide the axial compliance mentioned earlier in how the browser is operated. Stop collar 126 is provided to prevent the spring 109 from encroaching onto the region of the solder joint between the rod 111 and its semi-rigid (and tiny) coaxial cable. With these various above-described alterations, the browser 95 of FIG. 10 is used (i.e., is mechanically manipulated by an operator) in the same way as those of FIGS. 1-3.

There remains, however, the issue of what happens if the operator turns out to be a gorilla after all, despite warnings to the contrary. Only a few ounces of force can be tolerated at each probe tip without breakage, and the memory wire rods 110 and 111 are sized to deform before the damage level is reached. It will appreciated from the discussion of FIGS. 7-9 that the location of the convergence for the axes of rods 110 and 111 (90 and 91, respectively, in FIGS. 7-9) is fairly critical if proper contact between the conductive shields is to be maintained. This is one of the important reasons that using a memory metal is useful: it can be relied upon to return to its original shape with sufficient accuracy that proper contact between the conductive shields (at 92/93/94) is restored. Any attempt to bend regular wire back into shape with pliers would likely end in frustrating failure, especially if the rods had been ‘fixed’ before.

Thus, in accordance with the teaching of the incorporated UNBREAKABLE MICRO-BROWSER, the rods 127 and 128 may be either of the superelastic type that automatically returns to its set shape after deformation or of the ‘shape memory’ type that remains deformed but returns to it preset shape upon the application of mile heat, such as being immersed in hot water.

However, it will be noted that any bending of the rods 110 and 111 is almost certainly accompanied by a corresponding bend in the semi-rigid coaxial cables 112 and 113. How then, you might ask, is THAT damage to be dealt with?

Presumably the deforming bend in the semi-rigid coaxial cable(s) occurs not along the (stiff) solder joint to the rod(s) of memory metal, but somewhere on the S-curve or beyond. (The distance between the end of the rod of memory metal and the collar (75, 85) on the back of the conductive shield is kept to a minimum to lessen the chances that any bending occurs there, as that would not be protected by the memory metal and its ability to resume its shape. See again FIGS. 7-9.) The semi-rigid coax can simply be straightened with the fingers until is fits comfortably again within the slots of the grip. THAT fit is far less difficult to achieve, and far less critical, than the proper continued touching of the ends of the conductive shields at locations 92/93/94 as rod 91 rotates.

There is yet another solution to the problem of straightening accidently bent sections of semi-rigid transmissions lines 111 and 112, and that is to fabricate them from memory metal, as well. As with the rods, the sections of transmission line 111 and 112 could be either of the super elastic variety or of the shape memory variety. In the latter case, then the same application of low temperature heat that straightens the rods 127 and 128 would also return transmission lines 112 and 113 to their proper original shapes. (In either case, the fabricated lengths of rod and or transmission line would be properly shaped and then held in place by jigs while that shape is permanently ‘set’ by heating above a transition temperature.)

For the transmission lines there are several possibilities in this connection, and we shall digress briefly to merely mention them. The outer conductor of a coaxial transmission line can be of Nitinol, while the center conductor could either be of conventional copper or of silver or gold plated copper, or be of Nitinol, as well. The intervening dielectric could be any of the usual materials, such as polyethylene, polytetra fluroethylene (Teflon) or a foam variant of one of those. Nitinol by itself is not an outstanding conductor, so the resulting transmission line, if fabricated from pure Nitinol is rather lossy. This can be alleviated by plating the appropriate surfaces with either silver or gold. This is deemed practical even for the inner surface of the tube that would become the outer shield, owing to its rather short length (less than about two inches). Another memory metal that could be used in place of Nitinol is CuAlMn, which is somewhat more conductive than Nitinol, but not quite as elastic.

In any event, the magnetic resonance community has already investigated and described practical instances of memory metal coaxial transmission line structures in the range of 0.030″ to 0.036″ in overall diameter, and up to one meter long. They are used in a device called a MRIG (Magnetic Resonance Imaging Guidewire). See, for example, Development of an Intravascular Heating Source Using an MR Imaging Guidewire published in the JOURNAL OF MAGNETIC RESONANCE IMAGING 16:716-720 (2002), or, DEVELOPMENT AND APPLICATIONS OF INTRALUMINAL COILS FOR MRI, which is a thesis submitted in August 2002 by Andrew C. H. Yung to Johns Hopkins University.

The reader is also referred to the detailed description of Nitinol handling in the literature, e.g., Binary Phase Alloy Phase Diagrams, 2nd Ed. Vol. 3, published by William W. Scott, Jr., or, the ASM Handbook, Vol. 2, 1990. A particularly good collection of informative papers is the JOHNSON MATTHEY NiTi Smart Sheets.

It is practical to solder to Nitinol, as explained by an APPLICATION NOTE entitled “SOLDERING TO NITINOL” from the INDIUM CORPORATION OF AMERICA of 1676 Lincoln Avenue, Utica, N.Y., 13502, (315-853-4900).

Nitinol is available from suppliers, such as McMaster-Carr of Chicago, Ill., Small Parts in Miami Lake, Fla., or the Memry Corp. of Bethel, Conn.

Finally, we turn to FIGS. 11A-C that depict some alternate embodiments that do not involve off the shelf parts. FIG. 11A depicts a side view of a unitized probe tip assembly 116 that has a generally round conductive shield 122 having a collar 123 that connects to semi-rigid coaxial cable 124 in the manner previously described (e.g., soldering). Conductive shield 122 contains a shaft 117 that implements the coupling network. Region 120 of the shaft 117 is of high resistivity (corresponding to resistors 44/47 of FIG. 4) and shunted by a printed coupling capacitor 133 (corresponding to capacitors 45/48 in FIG. 4) that may be laser trimmed. Region 119 is a lower resistivity region having a sharp pointed tip 125, and corresponds to damping resistors 43/46 in FIG. 4. The center conductor (not shown) of the semi-rigid coax 124 is electrically connected to the internal end of the shaft 117. A raised boss 129 has a bore 129 therein that receives a rod 131 that carries the unitized probe tip assembly 116. Rod 131 corresponds to one of rods 127/128 of FIG. 10 or rods 90/91 of FIGS. 7-9. Rod 131 may be soldered into bore 129. Shaft 117 may be securely supported inside conductive shield 122 by a region 132 of suitable potting compound (e.g., epoxy).

There are a variety of way in which the shaft 117 can be made to produce the unitized probe tip assembly 116. One way is to start with a shaped shaft of alumina, deposit a coating of high resistivity onto region 120, print capacitor 133 over that, and deposit a coating of low resistivity onto region 119. A layer of conductive diamond can then be applied to region 118. Conductive diamond is applied in a known way by sintering diamond power. The conductive diamond coating on the region 118 (which includes tip 125) gives hardness for wear resistance.

Another way to fabricate shaft 117 is to form it of amorphous non-conductive diamond using CVD (Chemical Vapor Deposition). The shaft might be grown whole, or a core of alumina could be covered by the CVD diamond. The CVD diamond can be doped as it is grown to vary its resistivity, or it can be left non-conductive and coated afterward with resistive material.

We claim:

1. A voltage probe comprising:
an electrical coupling network having first and second distal ends a first length apart and generally along an axis of the electrical coupling network;
the electrical coupling network itself comprising at least two electrical components each of first and second terminals, the first terminals of the at least two electrical components being in direct mutual mechanical and electrical contact at the first distal end and the second terminals of the at least two electrical components also being in direct mutual mechanical and electrical contact at the second distal end; while the voltage probe also comprises
a conductive probe tip electrically and mechanically connected to the first distal end of the electrical coupling network;
a conductive shield axially surrounding the electrical coupling network for a substantial portion of the first length along the axis of the electrical coupling network while having an open end through which the electrical coupling network extends toward the first distal end and also having, opposite the open end, an aperture surrounding and proximate to the second distal end; and
a length of coaxial transmission line that passes through the aperture of the conductive shield, that has an outer shield that is electrically and mechanically connected to that aperture, and that also has a center conductor that is electrically connected to the second distal end of the electrical coupling network.

2. A voltage probe as in claim 1 wherein the at least two electrical components of the electrical coupling network comprise a capacitor in parallel with a resistor.

3. A voltage probe as in claim 2 wherein the electrical coupling network further comprises a third electrical component that is a damping resistance disposed in series between the conductive probe tip and the capacitor in parallel with the resistor.

4. A voltage probe as in claim 1 wherein the electrical coupling network is supported inside the conductive shield by a nonconductive potting compound.

5. A voltage probe as in claim 1 wherein the at least two electrical components of the electrical coupling network comprise surface mount components.

6. A voltage probe as in claim 3 wherein the third electrical component of the electrical coupling network comprises a surface mount resistor.

7. A voltage probe as in claim 1 wherein the length of coaxial transmission line comprises semi-rigid coax.

8. A voltage probe as in claim 1 wherein the length of coaxial transmission line comprises memory metal.

9. A voltage probe as in claim 1 further comprising a rod mechanically attached to the conductive shield proximate the aperture therein.

10. A voltage probe as in claim 9 wherein the rod comprises memory metal.

11. A voltage probe as in claim 1 further comprising a rod mechanically attached to the coaxial transmission line proximate the aperture in the conductive shield.

12. A voltage probe as in claim 11 wherein the rod comprises memory metal.

13. A hand held probe for electronic signals, comprising:
first and second rods;
a sleeve having first and second bores each sized to receive a respective one of the first and second rods, the axes of the bores in the sleeve being coplanar;
a first unitized probe assembly mechanically coupled to a first distal end portion of the first rod and having a first probe tip that extends beyond the perimeter of a first axial conductive shield that surrounds the first unitized probe assembly;
a second unitized probe assembly mechanically coupled to a first distal end portion of the second rod and having a second probe tip that extends beyond the perimeter of a second axial conductive shield that surrounds the second unitized probe assembly;
a second distal end of each of the first and second rods being carried within the respective one of the first and second bores in the sleeve;
the first unitized probe assembly being non-rotatable about the axis of the first rod;
the second unitized probe assembly being rotatable about the axis of the second rod;
a grip having axis and a bore therealong that receives the sleeve snugly to non-rotatably retain it, and also having first and second slots therein that are each parallel to the axis of the grip;
a first length of coaxial transmission line having an outer shield connected at a distal end thereof to the first axial conductive shield surrounding the first unitized probe assembly and also having an inner conductor that is electrically coupled to the first probe tip, a central portion of the first length of coaxial transmission line passing through the first slot in the grip;
a second length of coaxial transmission line having an outer shield connected at a distal end thereof to the second axial conductive shield surrounding the second unitized probe assembly and also having an inner conductor that is electrically coupled to the second probe tip, a central portion of the second length of coaxial transmission line passing through the second slot in the grip; and
the perimeter of the first conductive shield being in mechanical contact with the perimeter of the second conductive shield and remaining so as the second unitized probe assembly rotates about the axis of the second rod.

14. A hand held probe as in claim 13 wherein the first and second rods are sized to resist bending until the application of a selected force.

15. A hand held probe as in claim 14 wherein the first and second rods are of superelastic Nitinol.

16. A hand held probe as in claim 14 wherein the first and second rods are of shape memory Nitinol.

17. A hand held probe as in claim 13 further comprising a spring coupled between the sleeve and the combination of the second rod and second unitized probe assembly to resist force pushing the second rod into the second bore.

18. A hand held probe as in claim 16 wherein the spring is a spiral compression spring disposed over the second rod and located between the sleeve and the second unitized probe assembly.

19. A hand held probe as in claim 13 wherein the first and second probe tips of the first and second unitized probe assemblies are displaced from the axis of the respective rod to which each unitized probe assembly is attached and the distance between them varies as the second unitized probe assembly rotates about the axis of the second rod.

20. A hand held probe as in claim 13 wherein the first and second rods are retained within their respective first and second bores in the sleeve by friction caused by slight bends in the first and second rods within portions of those rods that enter those bores.

21. A hand held probe as in claim 13 wherein the axes of the bores in the sleeve converge along the direction toward the first and second probe tips to cause the perimeter of the first conductive shield to be in mechanical contact with the perimeter of the second conductive shield.

22. A hand held probe as in claim 13 wherein the axes of the bores in the sleeve are parallel and the first rod has a bend therein proximate its first distal end that causes the first conductive shield to be in mechanical contact with the perimeter of the second conductive shield.

22. A hand held probe as in claim 13 wherein the axes of the bores in the sleeve are parallel and the first rod has a bend therein proximate its first distal end that causes the first conductive shield to be in mechanical contact with the perimeter of the second conductive shield.

23. A hand held probe as in claim 13 wherein the first rod has a shape that is non-symmetrical about its axis and the first bore in the sleeve has a cross section that matches the shape of the first rod, such that the first rod is prevented from rotating within the first bore in the sleeve.

24. A hand held probe as in claim 13 wherein the first and second unitized probe assemblies each comprise surface mount components that are soldered directly to each other.

25. A hand held probe as in claim 13 wherein the surface mount components comprise a damping resistor in series with a coupling resistor in parallel with a capacitor.

26. A hand held probe as in claim 25 wherein the first and second conductive shields each have a rectangular cross section that includes rounded corners.

27. A hand held probe as in claim 13 wherein the first unitized probe assembly further comprises a first shaft having a pointed end that is the first probe tip and the second unitized probe assembly further comprises a second shaft having a pointed end that is the second probe tip.

28. A hand held probe as in claim 27 wherein the first and second shafts are of alumina coated with resistive material and each has a capacitive structure printed thereon.

29. A hand held probe as in claim 27 wherein the first and second shafts are of diamond.

30. A hand held probe as in claim 27 wherein the first and second shafts are of diamond formed by doped chemical vapor deposition and for each of the first and second shafts the doping is varied to create a region near the pointed end that has a low resistivity functioning as a damping resistance and the remainder of the shaft has a higher resistivity that is shunted by the capacitive structure printed thereon.

31. A hand held probe as in claim 27 wherein the pointed ends of the first and second shafts are coated with a layer of conductive diamond.

32. A hand held probe as in claim 27 wherein the first and second conductive shields each have a circular cross section.
